(19) United States
(12) Patent Application Publication
(10) Pub. No.: US 2008/0318349 A1
(43) Pub. Date: Dec. 25, 2008

(54) Wafer level hermetic bond using metal alloy

(75) Inventors: David M. Erlach, Santa Barbara, CA (US); Jeffery F. Summers, Santa Barbara, CA (US); Douglas L. Thompson, Santa Barbara, CA (US)

Correspondence Address: Jaquelin K. Spong, 2139 Dominion Way, Falls Church, VA, 22043, US

(73) Assignee: Innovative Micro Technology, Goleta, CA (US)

(21) Appl. No.: 12/222,845

(22) Filed: Aug. 18, 2008

Related U.S. Application Data
(62) Division of application No. 11/211,622, filed on Aug. 26, 2005.

(51) Int. Cl. H01L 21/56; H01L 21/67

(52) U.S. Cl. 438/15; 29/738; 257/E21.502

(57) ABSTRACT

Systems and methods for forming an encapsulated MEMS device include a hermetic seal which seals an insulating gas between two substrates, one of which supports the MEMS device. The hermetic seal may be formed by heating at least two metal materials, in order to melt at least one of the metal materials. The first melted metal material flows into and forms an alloy with a second metal material, forming a hermetic seal which encapsulates the MEMS device.

### CROSS REFERENCE TO RELATED APPLICATIONS

This U.S. patent application is a divisional application of U.S. patent application Ser. No. 11/211,622, filed Aug. 26, 2005. This U.S. patent application is related to U.S. patent application Ser. No. 11/211,623 (Attorney Docket No. IMT-Wallis), U.S. patent application Ser. No. 11/211,624 (Attorney Docket No. IMT-Blind Trench), and U.S. patent application Ser. No. 11/211,625 (Attorney Docket No. IMT-Interconnect), filed on an even date herewith, each of which is incorporated by reference in its entirety.

### STATEMENT REGARDING FEDERALLY SPONSORED RESEARCH

Not applicable.

### STATEMENT REGARDING MICROFICHE APPENDIX

Not applicable.

### BACKGROUND

This invention relates to the sealing of microelectromechanical systems (MEMS) devices in an enclosure and the method of manufacture of the sealed enclosure. In particular, this invention relates to the formation of a hermetic seal between a fabrication wafer supporting the MEMS devices, and a lid wafer.

Microelectromechanical systems (MEMS) are devices often having moveable components which are manufactured using lithographic fabrication processes developed for producing semiconductor electronic devices. Because the manufacturing processes are lithographic, MEMS devices may be batch fabricated in very small sizes. MEMS techniques have been used to manufacture a wide variety of sensors and actuators, such as accelerometers and electrostatic cantilevers.

MEMS techniques have also been used to manufacture electrical relays or switches of small size, generally using an electrostatic actuation means to activate the switch. MEMS devices often make use of silicon-on-insulator (SOI) wafers, which are a relatively thick silicon “handle” wafer with a thin silicon dioxide insulating layer, followed by a relatively thin silicon “device” layer. In the MEMS switches, a thin cantilevered beam of silicon is etched into the silicon device layer, and a cavity is created adjacent to the cantilevered beam, typically by etching the thin silicon dioxide layer to allow for the electrostatic deflection of the beam. Electrodes provided above or below the beam may provide the voltage potential which produces the attractive (or repulsive) force to the cantilevered beam, causing it to deflect within the cavity.

Because the MEMS devices often have moveable components, such as the cantilevered beam, they typically require protection of the moveable portions by sealing the devices in a protective cap or lid wafer, to form a device cavity. The lid wafer may be secured to the device layer by some adhesive means, such as a low outgassing epoxy. FIG. 1 shows an embodiment of an exemplary epoxy bond in a MEMS assembly 1. To achieve the epoxy bond, a layer of epoxy 20 is deposited on a cap or lid wafer 10, or on the fabrication wafer 30, around the perimeter of the MEMS device 34. The assembly 1 is then heated or the epoxy otherwise cured with wafer 10 pressed against the fabrication wafer 30, until a bond is formed between the cap or lid wafer 10 and the fabrication wafer 30. The bond forms a device cavity 40 which surrounds the MEMS device 34. The assembly 1 may then be diced to separate the individual MEMS devices 34.

### SUMMARY

However, the epoxy bond may not be hermetic, such that the gas with which the MEMS device is initially surrounded during fabrication, escapes over time and may be replaced by ambient air. In particular, if the MEMS device is an electrostatic MEMS switch is intended to handle relatively high voltages, such as those associated with telephone signals, the voltages may exceed, for example, about 400 V. For these relatively high voltages, it may be desirable to seal the electrostatic MEMS switch in an insulating gas environment, to discourage breakdown of the air and arcing between the high voltage lines. To this end, it may be desirable to seal an insulating gas such as sulphur hexafluoride SF₆ or a freon such as C₂Cl₂F₂ or C₂Cl₂F₄ within the device cavity. In order to maintain the gas environment around the electrostatic MEMS switch, the seal needs to be hermetic.

The systems and methods described here form a hermetic seal between a MEMS device layer and a cap or lid wafer. The seal construction may include an indium layer deposited over a gold layer. The gold and indium layers may be deposited by ion beam sputter deposition, by plating, or sputtering using a shadow mask to define the regions in which the gold and indium layers are to be deposited, for example. The gold and indium layers are then heated to a temperature beyond the melting point of the indium (156 C°). At this point, the indium melts into the gold and forms an alloy AuInₓ. The alloy AuInₓ may have the stoichiometry AuIn₂, and may be eutectic, such that it quickly solidifies. The alloy may be impermeable to insulating gases such as SF₆, and therefore may form a hermetic seal. Because indium melts at relatively low temperatures, the hermetic seal is formed at temperatures of only on the order of 150 degrees centigrade. The formation of the seal is therefore compatible with the presence of relatively vulnerable films, such as metal films, which would volatilize at temperatures of several hundred degrees centigrade. Nonetheless, because the alloy is stable to several hundred degrees centigrade, the seal may maintain its integrity up to these temperatures.

While the gold and indium layers may be deposited using lithographic patterning techniques, the systems and methods described here also include forming the seal using a metal insert, preformed with openings arranged in a manner consistent with the arrangement of MEMS devices as laid out on an SOI fabrication wafer. The metal insert may be stamped or etched from a thin metal sheet, and plated with indium metal. The SOI fabrication wafer and the cap or lid wafer may also be prepared with a deposited gold layer. The metal preformed insert may then be inserted between the SOI fabrication wafer and the cap or lid wafer. The fabrication wafer, the cap wafer and metal insert may then be sealed as before, by heating the assembly to form the alloy AuInₓ.

The systems and methods for forming the hermetic seal may therefore include forming a first metal layer on a first substrate around the MEMS device formed on the first substrate, forming a second metal layer on a second substrate, and coupling the first substrate to the second substrate with an alloy of the first metal and the second metal.

These and other features and advantages are described in, or are apparent from, the following detailed description.

### BRIEF DESCRIPTION OF THE DRAWINGS

Various exemplary details are described with reference to the following figures, wherein:

FIG. 1 is a cross sectional view of a prior art epoxy seal;

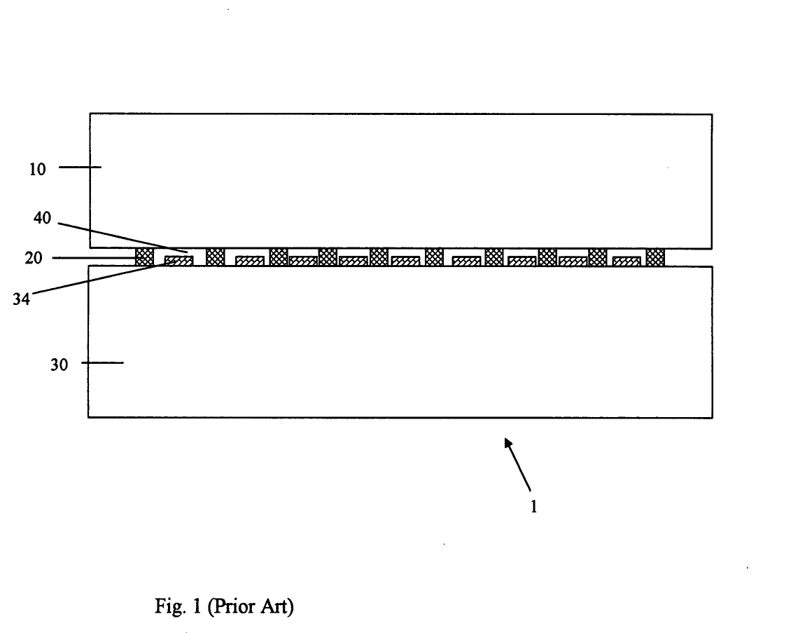

FIG. 2 is a cross sectional view showing an exemplary two-metal hermetic seal;

FIG. 3 is a cross sectional view showing an exemplary two-metal hermetic seal after formation of the metal alloy bond;

FIG. 4 is a cross sectional view showing the deposition of the first metal layer on the surface of an exemplary substrate using photolithographic patterning;

FIG. 5 is a cross sectional view showing the deposition of the first metal layer on the surface of an exemplary substrate using a shadow mask;

FIG. 6 is a cross sectional view of a first exemplary embodiment of a hermetic seal using a preformed metal insert;

FIG. 7 is a plan view showing the exemplary embodiment of FIG. 5;

FIG. 8 is a cross sectional view of the first exemplary embodiment of the hermetic seal using a preformed metal insert after formation of the alloy; and

FIG. 9 is a cross sectional view of a second exemplary embodiment of a hermetic seal using a preformed metal insert.

### DETAILED DESCRIPTION

In the systems and methods described here, a MEMS device is encapsulated with a cap or lid wafer. The MEMS device may have been previously formed on, for example, a silicon-on-insulator (SOI) composite substrate, or any other suitable substrate. The sealing mechanism may be a two-metal alloy, which bonds the silicon-on-insulator composite substrate with the cap or lid wafer. The two-metal alloy may have a melting point much higher than the melting point of either of the constituent elements, so that the alloy solidifies quickly upon formation. The alloy may form a hermetic seal, preventing an enclosed gas from leaking out of the enclosed area of the MEMS device. Because the seal is a metal alloy seal, it may also provide electrical continuity between the cap or lid wafer and the device wafer.

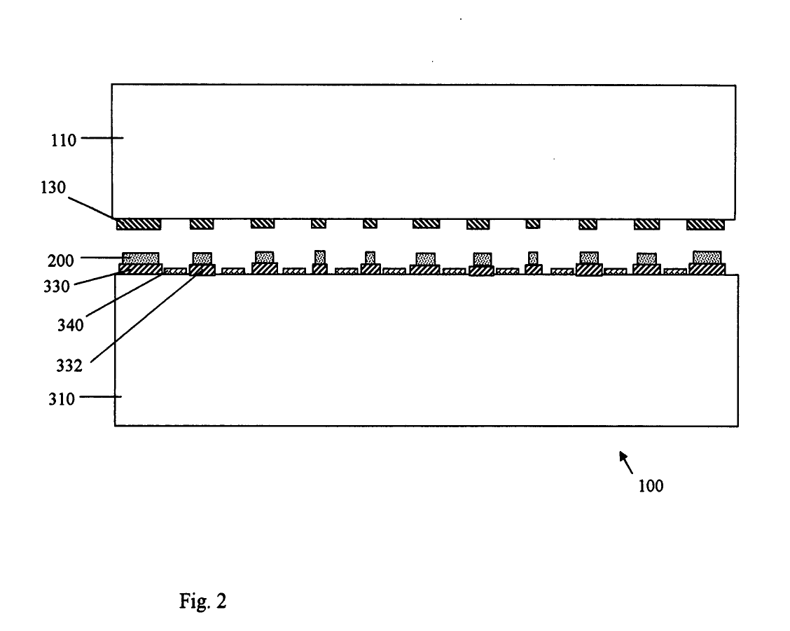

FIG. 2 shows a cross sectional view of an exemplary two-metal alloy sealed assembly 100 prior to formation of the hermetic seal. As shown in FIG. 2, the assembly 100 may include a first metal layer 130 deposited on a first substrate 110. The first substrate 110 may be a cap or lid wafer. Another metal layer 330 may be deposited on a second substrate 310, where metal layer 330 may be the same metal material as metal layer 130. Another metal layer 200 may be of a second metal material, and may be deposited over metal layer 330 on the second substrate 310. The second substrate 310 may be any suitable substrate, such as a silicon-on-insulator (SOI) substrate, upon which a plurality of MEMS devices 340 have been previously fabricated. The MEMS devices 340 may be located in areas between the metal layers, such as between metal layers 330 and 332 as shown schematically in FIG. 2. The first substrate may be any suitable material, including, for example, amorphous silicon, crystalline silicon, glass, quartz, or sapphire. Metal substrates may also be used, such as Kovar, a nickel-iron-cobalt alloy or Invar, a 36/64 alloy of nickel and iron. Both metals have a coefficient of thermal expansion closely matching that of silicon, which may be advantageous in terms of minimizing stress on the bond between the second substrate 310 and the first substrate 110.

It should be understood that metal layers 130 and 330 may be multilayers, rather than a single layer of metal material. For example, layers 130 and 330 may include an additional layer of metal within layer 130 or 330, to promote adhesion of metal layer 130 or metal layer 330 to substrate 110 or 310, respectively. For example, if the layers 130 and 330 are a gold layers, they may also include a thin layer of chromium (Cr) which promotes adhesion of the gold layers 130 and 330 to the surface of the substrate 110. The chromium layer may be, for example, about 50 Angstroms to about 200 Angstroms in thickness. Furthermore, there may also be diffusion barrier layers present, to prevent the diffusion of the metal of the adhesion layer into metal layer 130 or metal layer 330. For example, the gold layers 130 and 330 may also include a thin layer of molybdenum, about 100 Angstroms in thickness, which prevents the diffusion of the chromium adhesion layer into the gold layer, which would otherwise increase the electrical resistance of the metal layer 130. The remainder of metal layer 130 may be gold, which may be, for example, 3000 Angstroms to about 5000 Angstroms in thickness.

As illustrated in FIG. 2, metal layers 130 and 330 may be made wider than metal layer 200, in order to accommodate the outflow of metal layer 200 when metal layer 200 is heated beyond its melting temperature. For example, metal layers 130 and 330 may be made about 200 μm wide, whereas metal layer 200 may be made only about 80 to about 150 μm wide. Accordingly, when metal layer 200 is melted, and placed under pressure between metal layers 130 and 330, it may flow outward from the bond region. By making metal layers 130 and 330 wider than metal layer 200, the outflow of metal layer 200 may be accommodated while still keeping metal layer 200 between metal layer 130 and metal layer 330.

The surfaces of metal layers 200 and 130 may be cleaned to prepare the surfaces for bonding, and to enhance the strength of the alloy bond. The cleaning procedures may include ion milling over the surfaces, or dipping substrate 110 with metal layer 130, and substrate 310 with metal layers 330 and 200 into a solution of hydrochloric acid (HCl) or nitric acid. The hydrochloric or nitric acid may be used for the removal of the self-passivated metal oxide surface formed over the metal layers 130, 200 and 330. Oxygen plasmas may be used to remove residual photoresist left over from the previous processing, or any other organics which may otherwise interfere with the formation of the alloy bond. The oxygen plasma treatment may be performed before the acid dip.

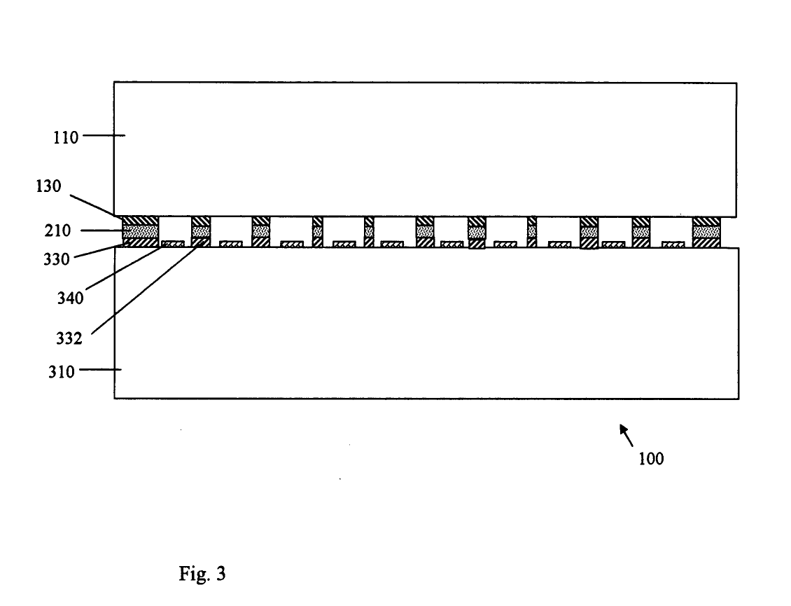

The material of metal layers 130, 200 and 330 may be chosen such that metal layers 130, 200 and 330 may form an alloy 210, as shown in FIG. 3. The alloy 210 may have a much higher melting point than the material of either metal layer 130, 330 or metal layer 200. The alloy 210 is formed by heating the assembly 100 beyond the melting point of the materials of either or both metal layer 130 and 330 and/or metal layer 200. Since the alloy 210 of metal layer 130 and 330 and metal layer 200 may have a melting point much higher than the original metal material of metal layer 130, 330 or metal layer 200, the alloy 210 may quickly solidify, sealing MEMS devices 340 in a hermetic seal.

In one exemplary embodiment, the first metal layer 130 and third metal layer 330 are gold (Au) and the second metal layer 200 is indium (In). The thicknesses of the gold layers 130 and 330 to the indium metal layer 200 may be in a ratio of about one-to-one by thickness. Since gold is about four times denser than indium, this ratio ensures that there is an adequate amount of gold in layers 130 and 330 to form the gold/indium alloy AuInₓ, where x is about 2, while still having enough gold remaining to ensure good adhesion to the substrates 110 and 310. The gold/indium alloy AuInₓ 210 may have a much higher melting point than elemental indium 200, such that upon formation of the alloy 210, it quickly solidifies, forming the hermetic bond. For example, the melting point of the gold/indium alloy may be 540 degrees centigrade, whereas the melting point of elemental indium is only 156 degrees centigrade.

Gold diffuses slowly into indium at room temperature and will diffuse fully into the indium at a temperature well below the melting temperature making the alloy AuInₓ which will not melt below 400 degrees centigrade. Care may therefore be taken to process and store the assembly at low temperatures to prevent the bond from forming before intended.

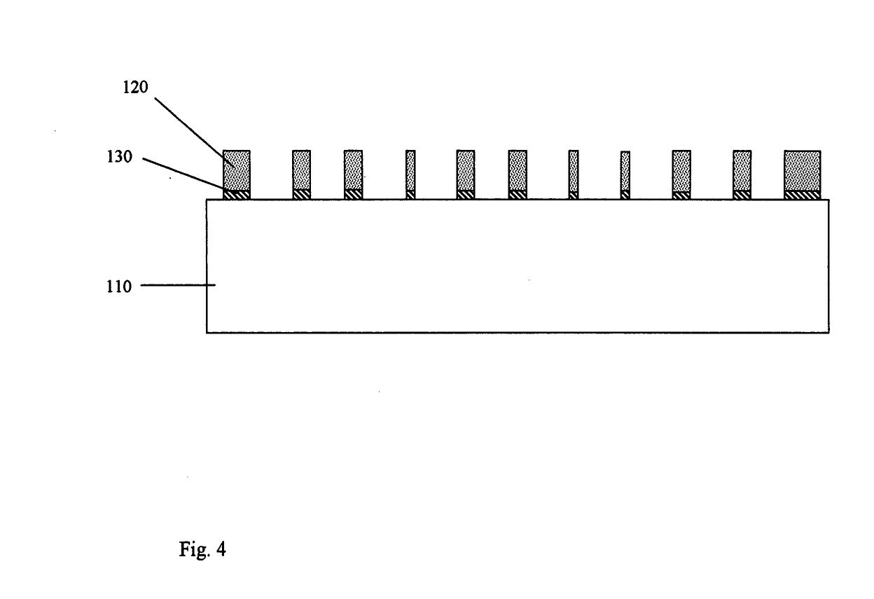

FIG. 4 is a cross sectional view showing an exemplary embodiment of a deposition procedure for depositing the gold layer 130 on the substrate 110. The substrate 110 may be, for example, a transparent glass substrate. In FIG. 4, the metal layer 130 is deposited over the entire surface of substrate 110. It should be understood that metal layer 130 may also be a multilayer, as described above. The surface of metal layer 130 may then be covered with photoresist 120 and patterned, as shown in FIG. 4. The patterning may be performed by exposing the surface of photoresist 120 though a mask, which illuminates only a portion of the photoresist 120 surface. If the photoresist 120 is a positive photoresist, the photoresist 120 is developed and removed in all areas in which it was exposed. If the photoresist 120 is a negative photoresist, the photoresist 120 is developed and removed in all areas in which it was not exposed. In either case, the photoresist 120 becomes patterned as shown in FIG. 4.

The metal layer 130 may then be ion milled to remove the material of metal layer 130 in any areas not covered by photoresist 120. The metal layer 130 may thus be located around the perimeter of each of the MEMS devices 340, as was shown in FIG. 2.

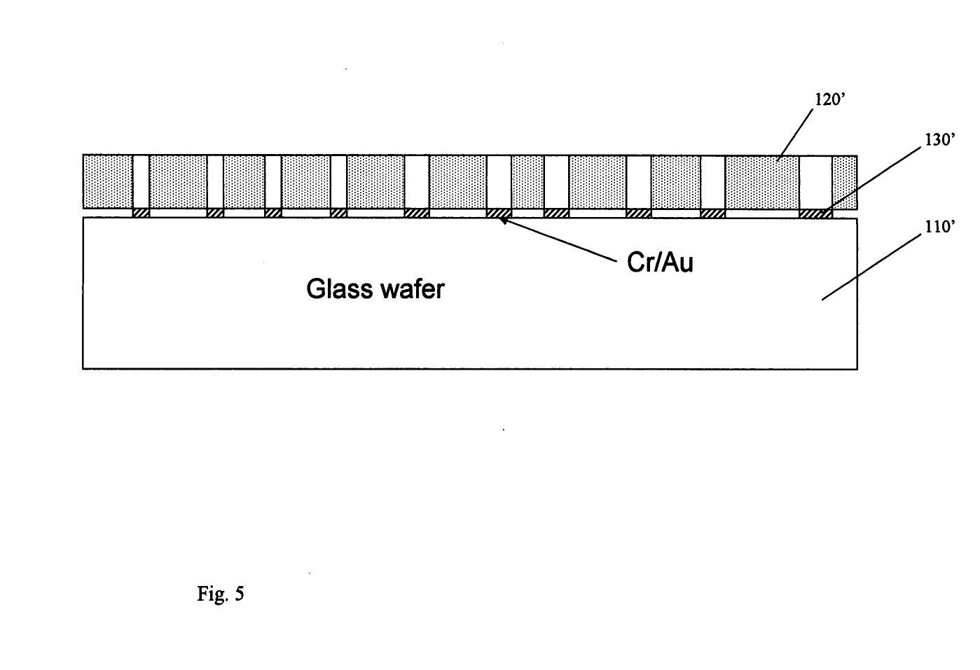

FIG. 5 shows a cross section of another exemplary embodiment of a deposition procedure for depositing the gold layer 130′ on the substrate 110′. In FIG. 5, a shadow mask 120′ is placed in front of the substrate 110′, while a layer of metal material 130′ is deposited on the substrate 110′. The presence of barriers 120′ in front of the substrate 110′ prevents the metal layer 130′ from being deposited in the areas shadowed by the barriers, thereby forming the pattern shown in FIG. 2. As with the previous embodiment shown in FIG. 4, the metal layer 130′ may actually be a multilayer, including an adhesion layer and a diffusion barrier layer, as well as the metal layer 130′.

Although the first metal layer 130 is described as being formed by milling or deposition through a shadow mask, it should be understood that any of a number of alternative deposition techniques may be used, such as sputter deposition through a patterned resist, followed by lift off of the resist.

It should be understood that the method used for depositing metal layer 330 on substrate 310 may be different than the method used to deposit metal layer 130 on substrate 110, because of the presence of the MEMS devices on substrate 310. For example, when depositing the metal layer 330 on substrate 300, a photoresist may first be deposited over the surface and the MEMS devices, and the photoresist patterned and removed over the areas in which it is desired to deposit the metal layer 330. Metal layer 330 is then deposited over the whole surface, and lifted off with the remaining photoresist in the areas in which the metal layer 330 is not desired. In another embodiment, metal layer 330 may be patterned as described above, whereas metal layer 130 may be left unpatterned.

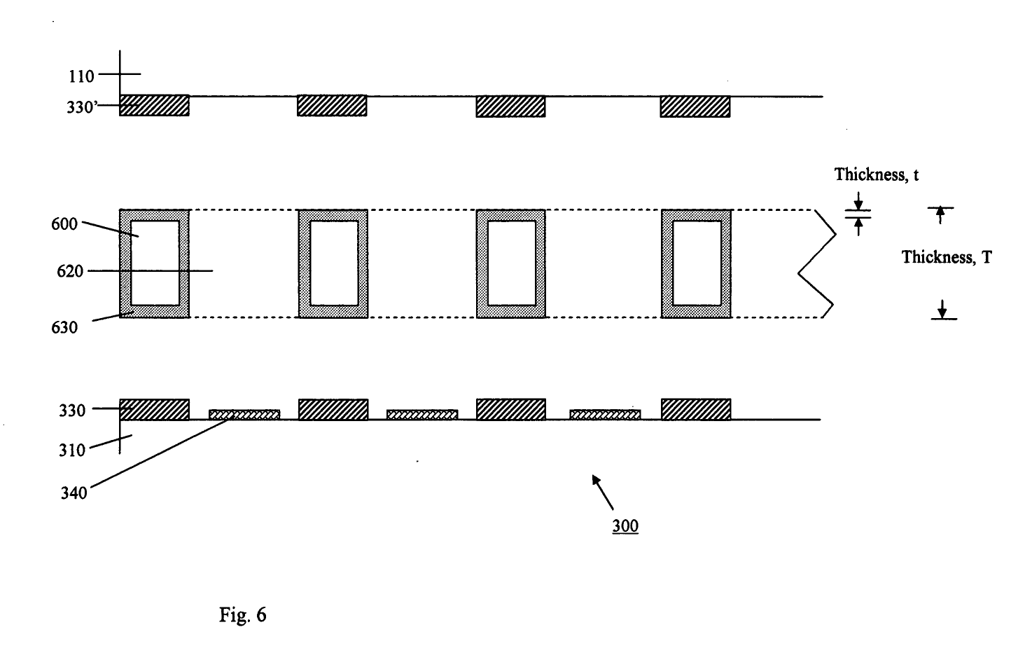

FIG. 6 shows a first exemplary embodiment of a hermetic seal using a preformed metal insert 600, on which the second metal material 630 has been deposited. For this embodiment, in contrast to the hermetic seal shown in FIG. 2, the first metal material may be applied in a layer 330 on the surface of the fabrication substrate 310 and also in another layer 330′ on the cap or lid wafer 110. As indicated by the reference number, the metal material in layer 330 may be, but is not necessarily, the same material as the metal material of layer 330′. The thickness of the metal films 330 and 330′ may be, for example, about 5000 Angstroms to about 1 μm thick. Layers 330′ or 330 may be deposited by any one of the processes described above. However, in another exemplary embodiment, metal layer 330′ may be deposited uniformly over substrate 110, respectively, without any patterning. In this case, the mesh of the preformed metal insert, coated with the second metal film, provides the material for the formation of the alloy seal only in the areas of the mesh, as described further below.

The preformed metal insert may be, for example, a copper, aluminum or stainless steel sheet of material 600, or any other suitable material, which has been processed to form openings 620. The openings 620 may be formed by stamping, etching, or milling for example. The openings 620 may be dimensioned so as to surround each of the MEMS devices 340. The thickness, T, of the metal sheet may be, for example, between about 30 μm to about 100 μm thick. After formation, the metal sheet 600 may be plated with the second metal material 630 to a thickness, t, of about 3 μm to about 6 μm. The second metal material 630 may be, for example, indium, plated by immersion in a plating bath for about 2 minutes, the plating bath being a solution of indium sulfate, indium sulfamate, sulfamic acid and sodium chloride. Suitable plating bath solutions may be obtained from Indium Corporation of Utica, N.Y.

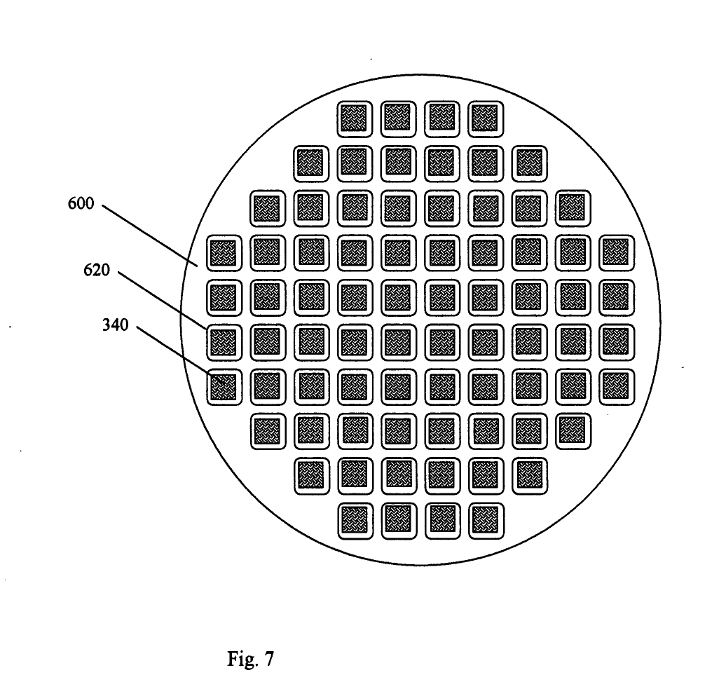

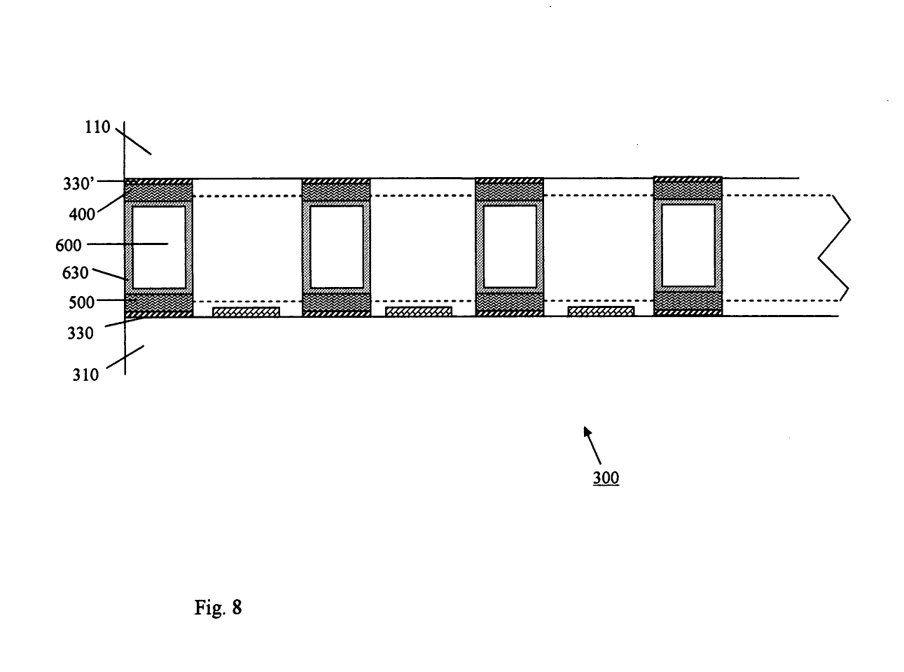

FIG. 7 is a plan view of preformed metal insert 600. As shown in FIG. 7, the openings 620 may be arranged in a regular pattern to surround each and every MEMS device 340 on the wafer 310. The placement of preformed metal insert 600 relative to the fabrication wafer 310 is first adjusted, until the openings 620 in preformed metal insert 600 are properly registered over each of the MEMS devices 340 on fabrication wafer 310. The preformed metal insert is then coupled to cap or lid wafer 110 and fabrication wafer 310, as shown in FIG. 8. The size of openings 620 may be sufficiently large to surround the MEMS device, and may be, for example, between about 50 μm and about 500 μm in at least one dimension, and may preferably be about 150 μm wide. The metal sheet 600 may be etched by depositing a sheet of photoresist on a disk of sheet metal 600, and exposing the photoresist through a mask patterned to correspond to the layout shown in FIG. 7. The photoresist may then be dissolved and removed in areas 620 corresponding to the location of the MEMS devices. The metal sheet 600 may then be etched in areas where the photoresist has been removed, by immersing the metal sheet 600 in, for example, a solution of hydrochloric acid. Alternatively, as mentioned above, the metal sheet may simply be stamped to form openings 620. Preferably, the deviation of the metal sheet 600 from flat may be less that the thickness of the plated second metal, over the dimensions of the openings 620.

The advantage of using preformed metal sheet 600 is that the processing required to make preformed metal sheet 600 may take place outside of the wafer fab, as the etching or stamping processes used to make preformed metal sheet 600 do not require clean room conditions. Furthermore, the plating of the second metal 630 may also be performed outside the clean room, by simply immersing the preformed metal sheet 600 in a metal plating bath. For example, to plate 4 μm of indium requires submersion in an indium plating bath for about 2 minutes. The preformed metal insert 600 may therefore be fabricated relatively cheaply and quickly.

FIG. 8 illustrates the assembly 300 including cap or lid wafer 110, preformed metal insert 600 and fabrication wafer 310. The assembly 300 may be held together by a clamp (not shown) during the heat treatment. The MEMS devices may be encapsulated in a preferred gas environment, for example, sulphur hexafluoride SF₆ or a freon, such as CCl₂F₂ or C₂Cl₂F₄, by backfilling a reaction chamber with about 2 atmospheres of the insulating gas. Alternatively, depending on the application, other gases may be used, for example, nitrogen (N₂). The MEMS devices may also be encapsulated in a vacuum or partial vacuum environment for cleanliness or performance reasons.

After cap or lid wafer 110 is aligned with the fabrication substrate 310 and preformed metal insert 600, the assembly 300 may be held together by the clamp with a clamping force of between about 100 to about 4000 Newtons, and heated to a temperature exceeding a melting temperature of at least one of the two metal materials 330 and 630. An alloy layer 400 then forms between the first metal layer 330′ and the second metal layer 630, and alloy 500 forms between first metal layer 330 and second metal layer 630. In the exemplary embodiment described above, first metal layer 330 and first metal layer 330′ are both gold, and second metal layer 630 is indium, such that alloy layers 400 and 500 are both an alloy of gold and indium, AuInₓ. In various exemplary embodiments, x is about 2, such that the stoichiometry of the alloy is AuIn₂. The process temperature for forming the gold/indium alloy 400 and 500 may be, for example, 160 to 180 degrees centigrade, whereas the melting point of indium is about 156 degrees centigrade. The assembly 300 is then allowed to dwell at this temperature for about 10 minutes. Thereafter, the assembly 300 may be cooled to room temperature before removing the clamp.

It may be important to assure that metal layers 330 and 330′ are sufficiently thick that a layer of pure metal remains over the cap or lid wafer 110 and over fabrication substrate 310, in order to assure good adhesion to these surfaces after formation of the alloy layers 400 and 500. Since gold is three to four times denser than indium, a gold layer about 4 μm thick may be appropriate to form a hermetic alloy seal with an indium layer plated to a thickness of 4 μm.

The material of the metal sheet 600 may be chosen to have a similar coefficient of thermal expansion compared to the metal alloy layers 400 and 500. The thermal coefficient of expansion (TCE) for silicon is 3 ppm. Some glasses (like Corning 7740) and metals (Invar or Kovar) are designed to have the same TCE as silicon. Use of these kinds of materials minimizes the strain on the MEMS wafer after bonding. While the indium tensile strength is very low, 273 psi, the AuInₓ alloy tensile strength is greater then 10,000 psi. Therefore, the hermetic seal formed with a gold/indium alloy 400 and 500 will not yield until a pressure in excess of (10,000 psi*area of bond) is applied to the bond. The area of the bond is around 0.0007 square inches, so that the force to break the lid off will be 10,000 psi*0.0007 in.=7 lbs of force.

Because of the extra height afforded to the assembly 300 by the presence of the preformed metal insert 600, the assembly 300 may be cut to expose electrical contacts under the cap or lid wafer 110, before the devices are singulated (i.e., separated) from one another on the fabrication wafer 310. The devices may therefore be probed and tested at the wafer level before final dicing to separate the devices. This may further reduce cost, by identifying bad devices or bad wafers, before the additional investment is made to singulate the packaged devices.

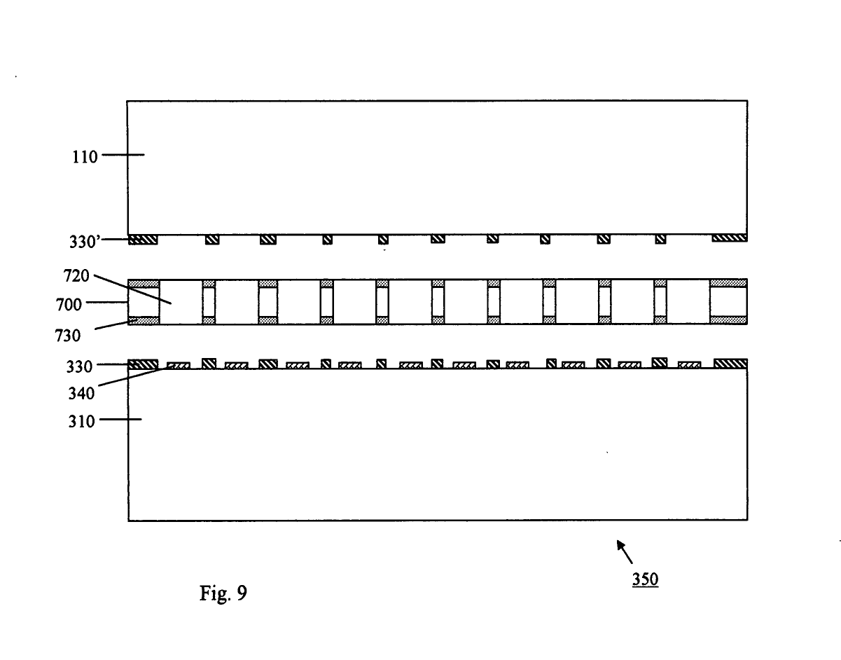

FIG. 9 illustrates a second exemplary embodiment of the hermetic seal assembly 350 formed using a preformed meal insert 700. Preformed metal insert 700 differs from preformed metal insert 600 by being stamped or etched after the deposition of the second metal layer 730. In this embodiment, a disk or sheet of metal material is plated with a layer of the second metal material 730, whereupon the disk or sheet 700 is stamped or etched to form openings 720. Because the second metal 730 is plated before the formation of the openings 720, the plated metal material 720 remains only on the top and bottom surfaces of preformed metal insert 700 after preformed metal insert 700 is etched or stamped. This embodiment may have the advantage of plating over a relatively pristine surface, without the debris which may occur as a result of the stamping or etching process. The pristine surface may yield a smoother, more uniform plated layer, since there is no surface debris to interfere with the plating of the ions from the plating bath to the surface of the substrate. The plating step may therefore result in a more smooth, uniform plated second metal layer 730.

While various details have been described in conjunction with the exemplary implementations outlined above, various alternatives, modifications, variations, improvements, and/or substantial equivalents, whether known or that are or may be presently unforeseen, may become apparent upon reviewing the foregoing disclosure. For example, while the disclosure describes the formation of a gold/indium alloy, it should be understood that the systems and methods described herein may be applied to any number of different alloy systems in addition to AuInₓ. Furthermore, while a number of alternatives are described for the formation of the metal layers, it should be understood that the metal layers may be formed by any number of alternative processes. Accordingly, the exemplary implementations set forth above, are intended to be illustrative, not limiting.

What is claimed is:

1. A method for encapsulating a device with a hermetic seal comprising:
forming a first layer of a first metal over a first substrate;
forming a second layer of a second metal over a second substrate; and
coupling the first substrate to the second substrate with an alloy formed from the first metal and the second metal, wherein the alloy has a substantially higher melting temperature than the first metal and the second metal.

2. The method of claim 1, wherein the alloy is a eutectic alloy.

3. The method of claim 2, wherein the eutectic alloy has a melting temperature in excess of 500 degrees centigrade.

4. The method of claim 1, wherein the first metal is a single metallic element.

5. The method of claim 4, wherein the second metal is also a single metallic element.

6. The method of claim 5, wherein the first single metallic element is indium and the second single metallic element is gold, and the alloy is AuInₓ, wherein x is about 2.

7. The method of claim 5, wherein the first single metallic element has a higher melting temperature than the second single metallic element, and wherein the first layer of the first single metallic element is wider that the second layer of the second single metallic element.

8. The method of claim 1, wherein the second substrate is a preformed metal insert, which is inserted between the first substrate and a third substrate, and which is plated with the second metal.

9. The method of claim 8, wherein the metal insert is preformed by at least one of stamping, etching and milling.

10. The method of claim 8, wherein a third layer of the first metal is formed on the third substrate, and wherein the first and third layers are wider than the second layer.

11. The method of claim 8, wherein the third substrate is a cap wafer, and comprises at least one of amorphous silicon, crystalline silicon, glass, quartz, sapphire and metal.

12. The method of claim 1, wherein the second substrate is a cap wafer, and comprises at least one of amorphous silicon, crystalline silicon, glass, quartz, sapphire and metal.

13. The method of claim 5, further comprising:
assembling the first substrate and second substrate together;
heating the first substrate and second substrate to a temperature exceeding a melting point of at least one of the first single metallic element and the second single metallic element; and
forming an alloy from the first single metallic element and the second single metallic element to form the hermetic seal.

14. The method of claim 13, further comprising:
evacuating a chamber containing the first substrate, second substrate and third substrate; and
filling the chamber with an insulating gas.

15. The method of claim 13, further comprising:
applying a force of between about 100 and about 4000 Newtons between the first substrate and the second substrate.

16. The method of claim 13, further comprising:
cutting through the second substrate to reveal electrical contacts; and
testing the device using the electrical contacts, before separating the device from other devices formed on the first substrate.

17. The method of claim 13, further comprising: cleaning a surface of the first single metallic element and the second single metallic element by at least one of ion milling and dipping into a solution including at least one of hydrochloric acid and nitric acid.

18. The method of claim 1, wherein forming the first layer and forming the second layer further comprises forming the first layer and the second layer with respective thicknesses such that a eutectic alloy is formed from the first metal and the second metal, when at least one of the first metal and the second metal is melted.

19. The method of claim 1, further comprising electrically connecting the first substrate to the second substrate with the alloy.

20. An apparatus for encapsulating a device with a hermetic seal comprising:
means for forming a first layer of a first metal over a first substrate;
means for forming a second layer of a second metal over a second substrate; and
means for coupling the first substrate to the second substrate with an alloy formed from the first metal and the second metal, wherein the alloy has a substantially higher melting temperature than the first metal or the second metal.
